(19) United States
(12) Patent Application Publication
(10) Pub. No.: US 2025/0180609 A1
(43) Pub. Date: Jun. 5, 2025

(54) POWER GATING SWITCH WITH CURRENT SENSOR

(71) Applicant: QUALCOMM Incorporated, San Diego, CA (US)

(72) Inventors: Khosrov DABBAGH SADEGHIPOUR, Cork (IE); Keith Anthony O DONOGHUE, Carrigaline (IE); Fikre Tsigabu GEBREYOHANNES, Midleton (IE)

(21) Appl. No.: 18/525,329

(22) Filed: Nov. 30, 2023

(51) Int. Cl. G01R 19/10; G01R 19/25

(52) U.S. Cl. CPC G01R 19/10; G01R 19/25

(57) ABSTRACT

A chip includes a power grid, power switches coupled between the power grid and a circuit, and current sensors configured to generate sense currents based on load currents passing through the power switches. The chip also includes a readout circuit having an input and an output, and signal routing coupling the current sensors to the input of the readout circuit.

### BACKGROUND

### Field

Aspects of the present disclosure relate generally to current sensing, and, more particularly, to current sensors integrated on a chip.

### Background

A chip may include a current-measurement circuit for measuring the current drawn by one or more circuits (e.g., one or more processor cores) on the chip. The current-measurement circuit may feed a signal indicating the measured current to a current-management circuit configured to manage the current of the one or more circuits. For example, the current-management circuit may compare the measured current with a current limit. If the measured current exceeds the current limit, then the current-management circuit may take steps to reduce the current (e.g., reduce a clock frequency of the one or more circuits).

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a power grid, power switches coupled between the power grid and a circuit, and current sensors configured to generate sense currents based on load currents passing through the power switches. The chip also includes a readout circuit having an input and an output, and signal routing coupling the current sensors to the input of the readout circuit.

A second aspect relates to a chip. The chip includes a first power grid configured to provide a first supply voltage, and a second power grid configured to provide a second supply voltage different from the first supply voltage. The chip also includes first power switches coupled between the first power grid and a first circuit, second power switches coupled between the second power grid and a second circuit, first current sensors configured to generate first sense currents based on first load currents passing through the first power switches, and second current sensors configured to generate second sense currents based on second load currents passing through the second power switches. The chip also includes a readout circuit having an input and an output, and signal routing coupling the first current sensors and the second current sensors to the input of the readout circuit.

A third aspect relates to a method for measuring current. The method includes generating sense currents based on load currents passing through power switches coupled between a power grid and a circuit, summing the sense currents to obtain a combined current, and converting the combined current into a digital signal.

A fourth aspect relates to a method for measuring current. The method includes generating first sense currents based on first load currents passing through first power switches coupled between a first power grid and a first circuit, and generating second sense currents based on second load currents passing through second power switches coupled between a second power grid and a second circuit, wherein the first power grid and the second power grid are in different voltage domains. The method also includes summing the first sense currents and the second sense currents to obtain a combined current, and converting the combined current into a digital signal.

### BRIEF DESCRIPTION OF THE DRAWINGS

FIG. 1A shows an example of a chip including a current-measurement circuit configured to measure currents passing through power switches based on voltage drops across the power switches according to certain aspects of the present disclosure.

FIG. 1B shows an example in which the power switches of FIG. 1A are closed to provide power to an integrated circuit according to certain aspects of the present disclosure.

FIG. 2 illustrates parasitic resistances in the chip of FIGS. 1A and 1B according to certain aspects of the present disclosure.

FIG. 3 shows an example of a current-measurement circuit including current sensors according to certain aspects of the present disclosure.

FIG. 4 illustrates parasitic resistances in the chip of FIG. 3 according to certain aspects of the present disclosure.

FIG. 5 shows an exemplary implementation of the current sensors of FIG. 3 according to certain aspects of the present disclosure.

FIG. 6 shows an exemplary implementation of a current mirror according to certain aspects of the present disclosure.

FIG. 7 shows an exemplary implementation of a current buffer according to certain aspects of the present disclosure.

FIG. 8 shows an exemplary implementation of a transimpedance amplifier according to certain aspects of the present disclosure.

FIG. 9 shows an example of a current-measurement circuit configured to measure current across a first voltage domain and a second voltage domain according to certain aspects of the present disclosure.

FIG. 10A shows an example of a power multiplexer configured to switch a circuit between the first voltage domain and the second voltage domain according to certain aspects of the present disclosure.

FIG. 10B shows an example of a processor core and a memory according to certain aspects of the present disclosure

FIG. 11 is a flowchart illustrating an exemplary method for measuring current according to certain aspects of the present disclosure.

FIG. 12 is a flowchart illustrating another exemplary method for measuring current according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

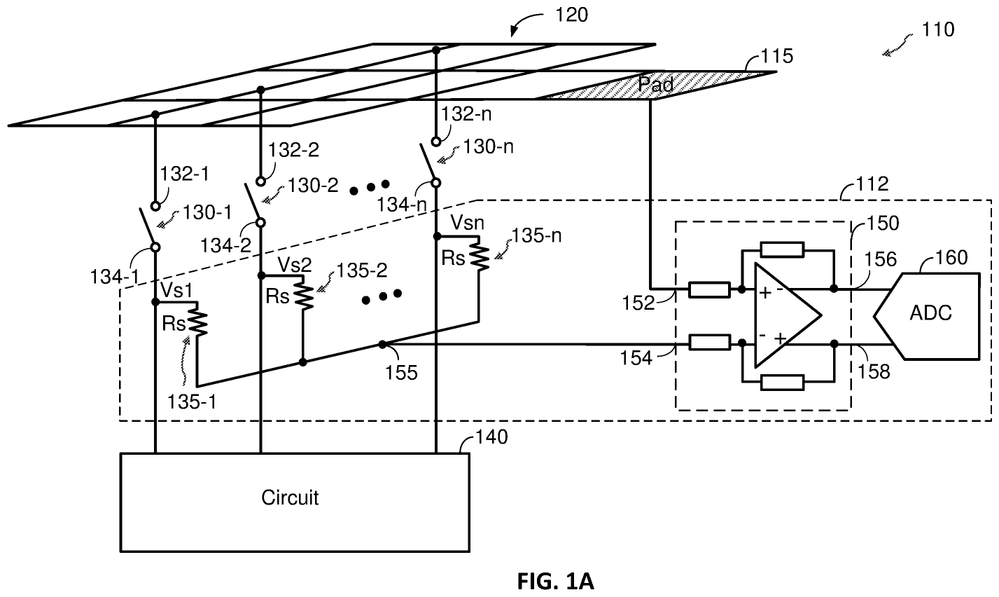

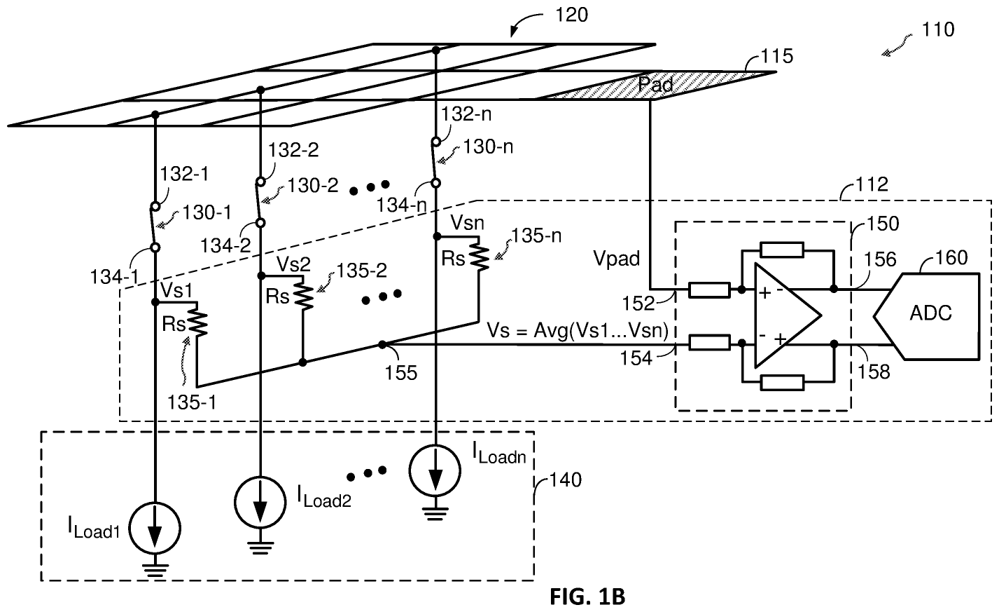

FIG. 1A shows an example of a chip 110 with integrated current sensing according to certain aspects of the present disclosure. The chip 110 includes a pad 115, a power grid 120, power switches 130-1 to 130-n, and an integrated circuit 140. The pad 115 may be coupled to an off-chip voltage source (e.g., a power management integrated circuit (PMIC)) to receive a supply voltage from the off-chip voltage source.

The power grid 120 is configured to distribute power from the pad 115 to the integrated circuit 140 (e.g., one or more processor cores). The power grid 120 may also be referred to as a power mesh, a supply rail, a power bus, or another term. The power grid 120 may be formed (i.e., patterned) from multiple metal layers of the chip 110 (e.g., using lithographic and etching processes). Although the power grid 120 is depicted as having a two-dimensional structure in FIG. 1A for case of illustration, it is to be appreciated that the power grid 120 may have a three-dimensional structure.

Each of the power switches 130-1 to 130-n has a first terminal 132-1 to 132-n and a second terminal 134-1 to 134-n, in which the first terminal 132-1 to 132-n is coupled to a respective node on the power grid 120 and the second terminal 134-1 to 132-n is coupled to the circuit 140. The power switches 130-1 to 130-n are used to selectively supply power to the circuit 140. For example, a power management circuit (not shown) may turn off the power switches 130-1 to 130-n to gate power to the circuit 140 when the circuit 140 is inactive to conserve power. The power management circuit may turn on the power switches 130-1 to 130-n to supply power to the circuit 140 when the circuit 140 is active. The power switches 130-1 to 130-n may also be referred to as power gating switches, head switches, or another term. Although FIG. 1A shows one row of the power switches 130-1 to 130-n for case of illustration, it is to be appreciated that the chip 110 may include an array of the power switches 130-1 to 130-n (e.g., global distributed head switch (GDHS)). In some implementations, each of the power switches 130-1 to 130-n is implemented with one or more p-type field effect transistors (PFETs). However, it is to be appreciated that the power switches 130-1 to 130-n are not limited to PFETs.

The chip 110 also includes a current-measurement circuit 112 configured to measure the current drawn by the circuit 140 based on the voltage drops across the power switches 130-1 to 130-n. In this example, the current-measurement circuit 112 includes resistors 135-1 to 135-n, an amplifier 150, and an analog-to-digital converter (ADC) 160. Each of the resistors 135-1 to 135-n is coupled between the second terminal 134-1 to 134-n of a respective one of the power switches 130-1 to 130-n and a collection node 155 (also referred to as a collection point). The amplifier 150 has a first input 152 coupled to the pad 115 and a second input 154 coupled to the collection node 155. The amplifier 150 also has a first output 156 and a second output 158 coupled to the ADC 160.

FIG. 1B shows an example in which the power switches 130-1 to 130-n are turned on (i.e., closed) to supply power to the circuit 140, and the circuit 140 draws current from the power grid 120 through the power switches 130-1 to 130-n. The current drawn by the circuit 140 includes load currents I_{Load1} to I_{Loadn} where each load current is the current passing through a respective one the power switches 130-1 to 130-n. In FIG. 1B, each load current I_{Load1} to I_{Loadn} is modeled by a respective current source in the circuit 140. The voltage drops across each power switch 130-1 to 130-n is approximately equal to the product of the respective load current and the on-resistance Rsw of the power switch 130-1 to 130-n. The on-resistance of each power switch 130-1 to 130-n is the resistance between the first terminal 132-1 to 132-n and the second terminal 134-1 to 134-n of the power switch 130-1 to 130-n when the power switch 130-1 to 130-n is turned on. For simplicity, the on-resistance Rsw is assumed to be the same for the power switches 130-1 to 130-n. The on-resistance Rsw of each power switch 130-1 to 130-n may be used as a current sense resistance for sensing the respective load current I_{Load1} to I_{Loadn}.

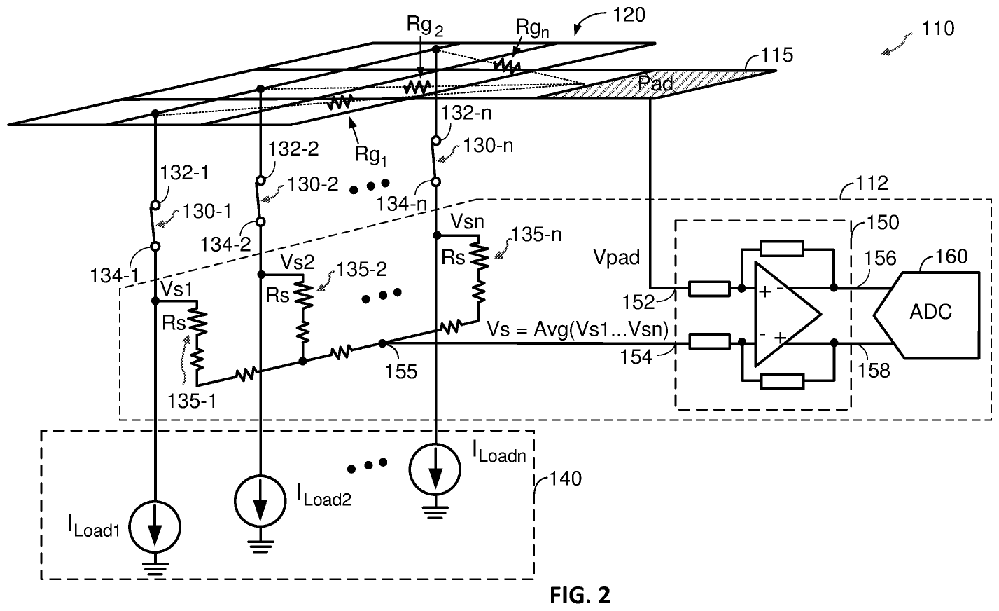

In the example in FIG. 1B, the resistors 135-1 to 135-n have the same resistance Rs and form an averaging resistor network. The averaging resistor network averages the voltages Vs1 to Vsn at the second terminals 134-1 to 134-n of the power switches 130-1 to 130-n to generate an average voltage Vs, which appears at the collection node 155. The average voltage Vs is given by the following:

$$Vs = \frac{{\sum }_{i = 1}^{n} Vsi}{n} = \frac{{\sum }_{i = 1}^{n} ( Vpad - {I}_{L oadi} Rsw )}{n} \qquad ( Eq . 1 )$$

where Vpad is the voltage at the pad 115, the subscript i in Vsi is an index for the power switches 130-1 to 130-n, and Rsw is the on-resistance of each power switch 130-1 to 130-n. Equation 1 assumes the ideal case of zero resistance in the power grid 120 and zero resistance in the signal routing between the resistors 135-1 to 135-n and the collection node 155. The non-ideal case of parasitic resistances in the power grid 120 and the signal routing is discussed later with reference to FIG. 2. The signal routing may also be referred to as a routing network.

In this example, the difference between the voltage Vpad at the pad 115 and the average voltage Vs at the collection node 155 is approximately equal to the average voltage drop across the power switches 130-1 to 130-n. Thus, the differential voltage (i.e., Vpad-Vs) between the first input 152 and the second input 154 of the amplifier 150 is approximately equal to the average voltage drop across the power switches 130-1 to 130-n. The amplifier 150 amplifies the average voltage drop across the power switches 130-1 to 130-n to generate a differential output voltage between the first output 156 and the second output 158. The output voltage of the amplifier 150 is given by the following:

$$Vout = k ( Vpad - Vs ) = k ( Vpad - \frac{{\sum }_{i = 1}^{n} ( Vpad - {I}_{Loadi} Rsw )}{n} ) \qquad ( Eq . 2 )$$

where Vout is the output voltage of the amplifier 150 and k is the gain of the amplifier 150. In Equation 2, the pad voltage Vpad at the first input 152 of the amplifier 150 is canceled by the Vpad component in the voltage Vs at the second input 154 of the amplifier 150. Equation 2 can be rewritten to the following:

$$Vout = \frac{kRsw}{n} {\sum }_{i = 1}^{n} {I}_{Loadi} \qquad ( Eq . 3 )$$

Thus, the output voltage of the amplifier 150 is a linear function of the total load current of the circuit 140 in the ideal case, and therefore provides a measurement of the current drawn by the circuit 140.

The ADC 160 converts the output voltage of the amplifier 150 into a digital current measurement, which provides a measurement of the current drawn by the circuit 140 in the digital domain. The ADC 160 may output the digital current measurement to a current-management circuit (not shown in FIGS. 1A and 1B), which may manage the current drawn by the circuit 140 based on the digital current measurement and a current limit.

The current-measurement circuit 112 is discussed above for the ideal case of zero resistance in the power grid 120 and zero resistance in the signal routing between the resistors 135-1 to 135-n and the collection node 155. However, in practice, the power grid 120 has parasitic resistances and the signal routing between the resistors 135-1 to 135-n and the collection node 155 has parasitic resistances. The current-measurement circuit 112 is sensitive to these parasitic resistances because the current-measurement circuit 112 measures the current based on the voltage drops across the power switches 130-1 to 130-n. As a result, the accuracy of the current-measurement circuit 112 may be negatively impacted by the parasitic resistances.

The parasitic resistances in the power grid 120 and the parasitic resistances in the signal routing between the resistors 135-1 to 135-n and the collection node 155 are illustrated in FIG. 2. In FIG. 2, the parasitic grid resistances for the power switches 130-1 to 130-n are represented by the resistors Rg₁ to Rgₙ, respectively. The parasitic grid resistances Rg₁ to Rgₙ for the power switches 130-1 to 130-n may be different since the power switches 130-1 to 130-n are coupled to different nodes on the power grid 120. The current-measurement circuit 112 is sensitive to the parasitic grid resistances Rg₁ to Rgₙ because the current-resistor (IR) voltage drops across the parasitic grid resistances Rg₁ to Rgₙ affect the differential voltage input to the amplifier 150. The sensitivity of the current-measurement circuit 112 to the parasitic grid resistances Rg₁ to Rgₙ may be reduced by making the on-resistances Rsw of the power switches 130-1 to 130-n larger relative to the parasitic grid resistances Rg₁ to Rgₙ. However, it is desirable to keep the on-resistances Rsw of the power switches 130-1 to 130-n small to minimize the voltage drops between the power grid 120 and the circuit 140.

In FIG. 2, the parasitic routing resistances between the resistors 135-1 to 135-n and the collection node 155 are represented by resistors in the signal routing between the resistors 135-1 to 135-n and the collection node 155. The parasitic routing resistances for the resistors 135-1 to 135-n may be different. This is because the lengths of the signal routing between the resistors 135-1 to 135-n and the collection node 155 vary from resistor to resistor depending on the locations of the resistors 135-1 to 135-n and the location of the collection node 155.

The different parasitic routing resistances for the resistors 135-1 to 135-n cause the collection node 155 to generate a weighted average of the voltages Vs1 to Vsn, in which the voltages Vs1 to Vsn are weighted differently depending on the parasitic routing resistances for the respective resistors 135-1 to 135-n. The different weights due to the different parasitic routing resistances for the resistors 135-1 to 135-n can reduce the accuracy of the current-measurement circuit 112.

Since the parasitic routing resistances for the resistors 135-1 to 135-n depend on the location of the collection node 155, the weights for the voltages Vs1 to Vsn in the weighted average also depend on the location of the collection node 155. As a result, some potential locations for the collection node 155 may provide higher accuracy for the current-measurement circuit 112 than other potential locations for the collection node 155. In this regard, a detailed analysis (e.g., vector analysis) of the current-measurement circuit 112 using different potential locations for the collection node 155 may be performed (e.g., using a computer simulations) to find an optimal location for the collection node 155. However, finding the optimal location for the collection node 155 may complicate the design of the current-measurement circuit 112, and, more importantly, may not guarantee a desired current-measurement accuracy.

To address the above limitations of the voltage-drop based current sensing, aspects of the present disclosure provide a current-measurement circuit that measures current using current-mode current sensing. The current-measurement circuit includes current sensors configured to sense the load currents passing through power switches and generate sense currents based on the sensed load currents. The sense currents are summed at a collection node and input to readout circuitry, which may include a transimpedance amplifier and an ADC. Because the current-measurement circuit uses current-mode current sensing, the current-measurement circuit is not sensitive to parasitic grid resistances and parasitic routing resistances. Further, the pad voltage does not need to be routed to one of the input terminals of the amplifier to cancel the pad voltage component in the voltage Vs at the other input terminal of the amplifier. Hence, circuitry required to set the input common-mode voltage of the amplifier and the complexities and limitations resulting from such arrangement are avoided using the current-mode current measurement approach. The above features and other features of the present disclosure are discussed further below.

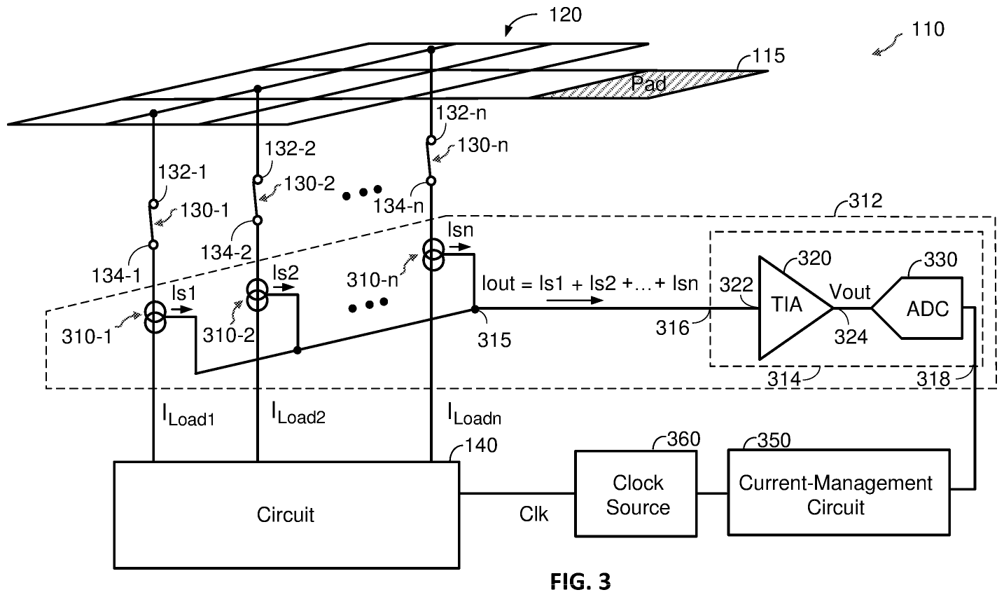

FIG. 3 shows an example of a current-measurement circuit 312 using current-mode current sensing according to certain aspects of the present disclosure. The current-measurement circuit 312 includes current sensors 310-1 to 310-n and a readout circuit 314. Each of the current sensors 310-1 to 310-n is coupled to a respective one of the power switches 130-1 to 130-n and a collection node 315. The readout circuit 314 has an input 316 coupled to the collection node 315, and an output 318.

Each of the current sensors 310-1 to 310-n is configured to sense the load current I_{Load1} to I_{Loadn} of the respective power switch 130-1 to 130-n and generate a respective sense current Is1 to Isn based on the respective sensed load current. For example, the sense current Is1 to Isn of each current sensor 310-1 to 310-n may be proportional to the load current I_{Load1} to I_{Loadn} of the respective power switch 130-1 to 130-n in some implementations. The sense current Is1 to Isn are summed at the collection node 315 (also referred to as a summing node) to generate an output current Iout. The chip 110 includes signal routing coupling the current sensors 310-1 to 310-n to the input 316 of the readout circuit 314 as shown in FIG. 3. The signal routing includes the collection node 315 and may be formed (i.e., patterned) from one or more metal layers of the chip 110 (e.g., using lithographic and etching techniques).

The readout circuit 314 is configured to receive the output current Iout (i.e., the sum of the sense currents Is1 to Isn) at the input 316, and convert the output current Iout into a digital current measurement. The readout circuit 314 may output the digital current measurement to a current-management circuit 350, which may manage the current drawn by the circuit 140 based on the digital current measurement. For example, the current-management circuit 350 may compare the digital current measurement with a current limit. If the digital current measurement exceeds the current limit, then the current-management circuit 350 may take steps to reduce the current drawn by the circuit 140 (e.g., reduce the clock frequency of the circuit 140 to reduce the current, gate the power switches 130-1 to 130-n, etc.). In this regard, FIG. 3 shows an example in which the chip 110 includes a clock source 360 (e.g., phase locked loop (PLL)) coupled to the circuit 140 and the current-management circuit 350. The clock source 360 generates and outputs a clock signal Clk to the circuit 140 to time operations of the circuit 140. In this example, the current-management circuit 350 may cause the clock source 360 to reduce the frequency of the clock signal Clk if the digital current measurement exceeds the current limit. However, it is to be appreciated that the current-management circuit 350 is not limited to clock frequency throttling to manage current and may employ other techniques to manage current consumption.

In the example shown in FIG. 3, the readout circuit 314 includes a transimpedance amplifier (TIA) 320 and an ADC 330. The transimpedance amplifier 320 has an input 322 coupled to the collection node 315, and an output 324 coupled to the ADC 330. The transimpedance amplifier 320 is configured to receive the output current Iout (i.e., the sum of the sense currents Is1 to Isn) at the input 322, and convert the output current Iout into an output voltage Vout at the output 324, which is input to the ADC 330. The ADC 330 is configured to convert the output voltage Vout into the digital current measurement, which may be output to the current-management circuit 350.

It is to be appreciated that the readout circuit 314 is not limited to the transimpedance amplifier 320 and the ADC 330. The readout circuit 314 may be implemented with any suitable circuit configured to convert the output current Iout into a digital current measurement or any other form of usable signal. For example, in other implementations, the readout circuit 314 may include a ring oscillator and a counter. In this example, the output current Iout may be fed to the ring oscillator to convert the output current Iout into a frequency, and the counter may convert the frequency into a digital current measurement.

It is to be appreciated that the power switches 130-1 to 130-n may be a subset of all of the power switches coupled between the power grid 120 and the circuit 140. In this example, the power switches 130-1 to 130-n may be chosen from among all of the power switches coupled between the power grid 120 and the circuit 140 to provide a representative sample of the current drawn by the circuit 140.

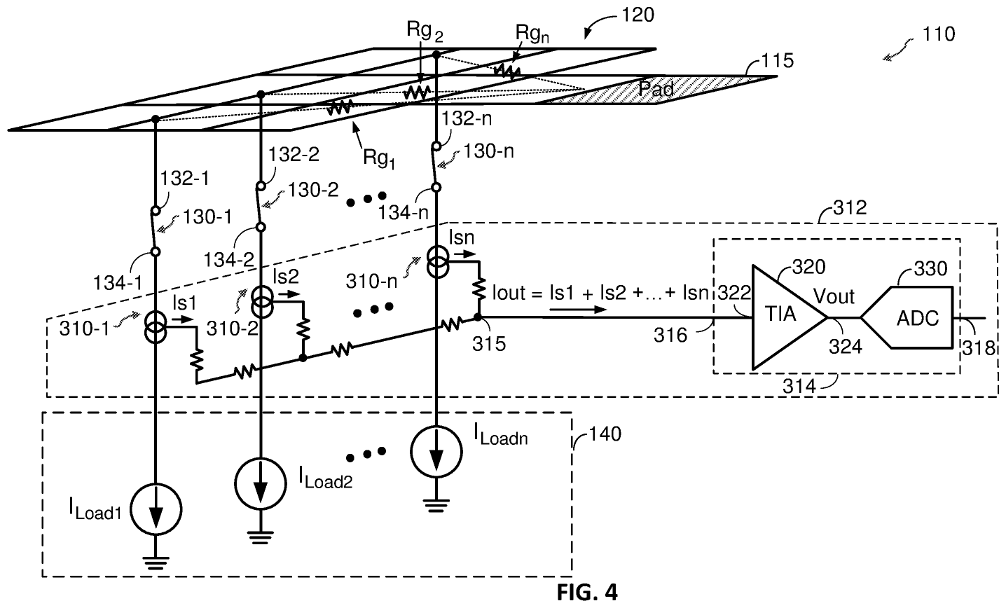

FIG. 4 illustrates the current-measurement circuit 312 with parasitic grid resistances Rg₁ to Rgₙ and parasitic routing resistances in the signal routing between the current sensors 310-1 to 310-n and the collection node 315. The current-measurement circuit 312 is not sensitive to the parasitic grid resistances Rg₁ to Rgₙ since the current sensors 310-1 to 310-n sense the load currents current I_{Load1} to I_{Loadn} passing through the power switches 130-1 to 130-n. In contrast, in the current-measurement circuit 112, IR voltage drops across the parasitic grid resistances Rg₁ to Rgₙ affect the differential voltage (i.e., Vpad-Vs) input to the amplifier 150.

The current-measurement circuit 312 is also not sensitive to parasitic routing resistances in the signal routing between the current sensors 310-1 to 310-n and the collection node 315. This is because the signal routing in the current-measurement circuit 312 routes currents Is1 to Isn, which are not sensitive to parasitic routing resistances. Since the current-measurement circuit 312 is not sensitive to parasitic routing resistances, the current-measurement circuit 312 is not sensitive to differences in the parasitic routing resistances in the different branches of the signal routing. As a result, the current-measurement circuit 312 is not sensitive to the location of the collection node 315, which may eliminate the need for performing simulations (e.g., test vector simulations) to find an optimal location for the collection node. Also, since the current-measurement circuit 312 is not sensitive to parasitic routing resistances, the signal routing does not require low parasitic routing resistances. This allows the signal routing to be narrower, which helps alleviate congestion in the metal layers of the chip 110.

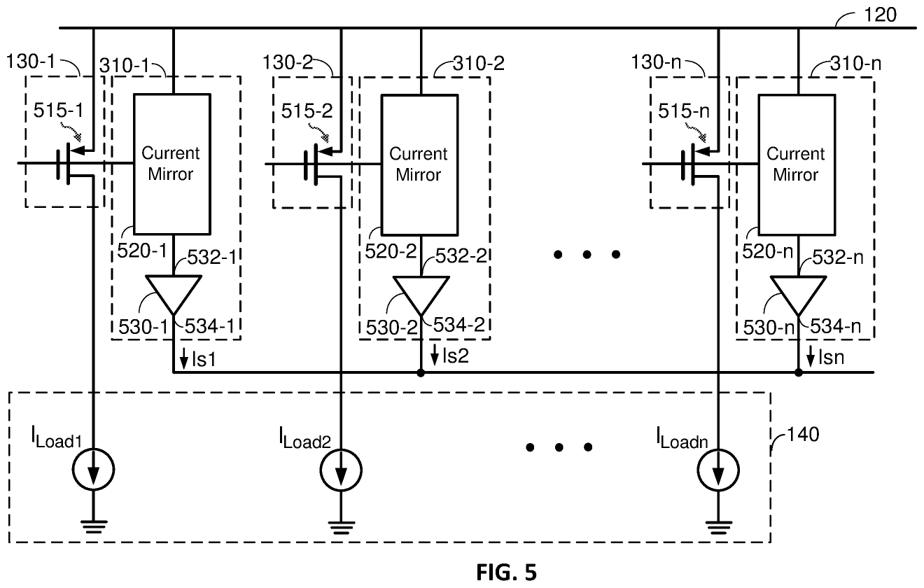

FIG. 5 shows an exemplary implementation of the power switches 130-1 to 130-n and the current sensors 310-1 to 310-n according to certain aspects. In the example shown in FIG. 5, each of the power switches 130-1 to 130-n is implemented with a respective switch transistor 515-1 to 515-n (e.g., a respective p-type field effect transistor (PFET)). In this example, the on/off state of each of the power switches 130-1 to 130-n is controlled by the voltage applied to the gate of the respective switch transistor 515-1 to 515-n. Each of the switch transistors 515-1 to 515-n may be physically implemented on the chip 110 with multiple transistors coupled in parallel in which the gates of the multiple transistors are coupled together. For the example where each of the switch transistors 515-1 to 515-n is implemented with a respective PFET, each of the switch transistors 515-1 to 515-n may be turned off by applying a high voltage (e.g., a supply voltage) to the respective gate and turned on by applying a low voltage (e.g., ground potential) to the respective gate.

In the example shown in FIG. 5, the source of the each of the switch transistors 515-1 to 515-n is coupled to the power grid 120, which is represented by a straight line in FIG. 5 for ease of illustration. The power grid 120 may also be referred to as a power bus, a power mesh, a supply rail, or another term. The drain of each of the switch transistors 515-1 to 515-n is coupled to the circuit 140 (e.g., one or more processor cores).

In the example in FIG. 5, each of the current sensors 310-1 to 310-n includes a respective current mirror 520-1 to 520-n and a respective current buffer 530-1 to 530-n. Each current mirror 520-1 to 520-n is coupled to the power grid 120 and the gate of the respective switch transistor 515-1 to 515-n (e.g., respective PFET). Each current mirror 520-1 to 520-n is configured to mirror the load current I_{Load1} to I_{Loadn} passing through the respective switch transistor 515-1 to 515-n to generate the respective sense current Is1 to Isn. In certain aspects, each sense current Is1 to Isn is proportional to the respective load current I_{Load1} to I_{Loadn}. For example, each sense current Is1 to Isn may be approximately equal to the respective load current I_{Load1} to I_{Loadn} divided by N where N is a scaling factor greater than one. Thus, in this example, each sense current Is1 to Isn is a scaled-down version of the respective load current I_{Load1} to I_{Loadn}.

In this example, each current buffer 530-1 to 530-n has a respective input 532-1 to 532-n coupled to the respective current mirror 520-1 to 520-n, and a respective output 534-1 to 534-n coupled to the signal routing to the readout circuit 314 (shown in FIGS. 3 and 4). The signal routing may also be referred to as a routing network or another term. In certain aspects, each current buffer 530-1 to 530-n has unity current gain, in which the current buffer 530-1 to 530-n passes the sense current Is1 to Isn from the respective current mirror 520-1 to 520-n to the signal routing shown in FIGS. 3 and 4. The current buffers 530-1 to 530-n may be used, for example, to isolate the respective current mirrors 520-1 to 520-n from the loads of the signal routing and the readout circuit 314.

For the example where each sense current Is1 to Isn is equal to the respective current I_{Load1} to I_{Loadn} divided by N, the sum of the sense currents Is1 to Isn input to the readout circuit 314 is given by:

$$Iout = \frac{1}{N} {\sum }_{i = 1}^{n} {I}_{Loadi} \qquad ( Eq . 4 )$$

where Iout is the sum of the sense currents Is1 to Isn at the collection node 315. The readout circuit 314 may convert the current Iout into the digital current measurement discussed above. For the example where the readout circuit 314 includes the transimpedance amplifier 320 and the ADC 330, the output voltage of the transimpedance amplifier 320 may be given by:

$$Vout = \frac{k}{N} {\sum }_{i = 1}^{n} {I}_{Loadi} \qquad ( Eq . 5 )$$

where k is the gain of the transimpedance amplifier 320. In this example, the output voltage Vout is input to the ADC 330, which converts the output voltage Vout into the digital current measurement discussed above.

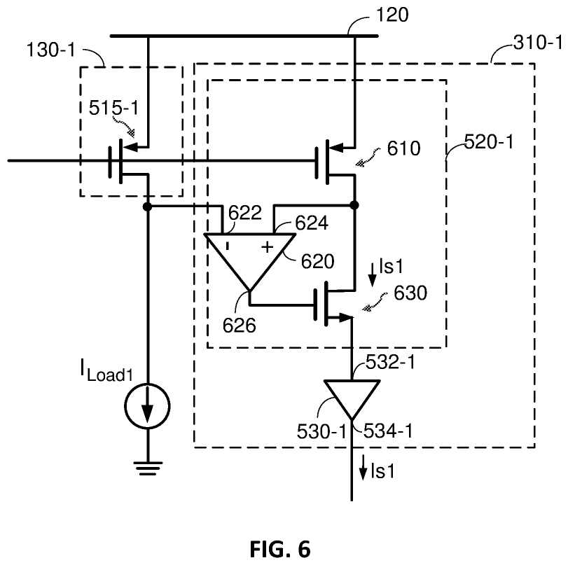

FIG. 6 shows an exemplary implementation of the current mirror 520-1 in the current sensor 310-1 according to certain aspects. It is to be appreciated that each of the other current mirrors 520-2 to 520-n may be implemented with the exemplary implementation shown in FIG. 6 (e.g., each of the other current mirrors 520-2 to 520-n may be a separate instance of the implementation shown in FIG. 6).

In this example, the current mirror 520-1 includes a sense transistor 610, an amplifier 620, and a feedback transistor 630. The source of the sense transistor 610 (e.g., a PFET) is coupled to the power grid 120, the gate of the sense transistor 610 is coupled to the gate of the switch transistor 515-1, the drain of the feedback transistor 630 (e.g., an n-type field effect transistor (e.g., NFET)) is coupled the drain of the sense transistor 610, and the source of the feedback transistor 630 is coupled to the input 532-1 of the respective current buffer 530-1. In this example, the gate voltage of the sense transistor 610 is approximately equal to the gate voltage of the switch transistor 515-1 since their gates are coupled together.

The amplifier 620 has a first input 622, a second input 624, and an output 626. The amplifier 620 may be powered by the power grid 120. In the example in FIG. 6, the first input 622 is coupled to the drain of the switch transistor 515-1, the second input 624 is coupled to the drain of the sense transistor 610, and the output 626 is coupled to the gate of the feedback transistor 630. In this example, the amplifier 620 and the feedback transistor 630 form a feedback loop that causes the amplifier 620 to adjust the gate voltage of the feedback transistor 630 in a direction that forces the voltage at the second input 624 of amplifier 620 to be approximately equal to the voltage at the first input 622 of the amplifier 620. Since the first input 622 of the amplifier 620 is coupled to the drain of the switch transistor 515-1 and the second input 624 of the amplifier 620 is coupled to the drain of the sense transistor 610, the feedback loop forces the voltage at the drain of the sense transistor 610 to be approximately equal to the voltage at the drain of the switch transistor 515-1. As a result, the source-to-drain voltage of the sense transistor 610 is approximately equal to the source-to-drain voltage of the switch transistor 515-1, and the gate voltage of the sense transistor 610 is approximately equal to the gate voltage of the switch transistor 515-1. This causes the sense current Is1 flowing through the sense transistor 610 to mirror the load current I_{Load1} flowing through the switch transistor 515-1. The sense current Is1 flows through the feedback transistor 630 to the input 532-1 of the current buffer 530-1, which outputs the sense current Is1 to the signal routing shown in FIG. 5.

In certain aspects, the sense current Is1 is proportional to the load current I_{Load1}. For example, in some implementations, the switch transistor 515-1 may be implemented with N transistors coupled in parallel while the sense transistor 610 may be implemented with one transistor having the same size as each of the N transistors. In this example, the sense current Is1 may be approximately equal to the load current I_{Load1} divided by N. Thus, in this example, the sense current Is1 is a scaled-down version of the load current I_{Load1} passing through the switch transistor 515-1.

It is to be appreciated that the current mirror 520-1 is not limited to the exemplary implementation shown in FIG. 6, and that the current mirror 520-1 may be implemented with other configurations of transistors and/or amplifiers.

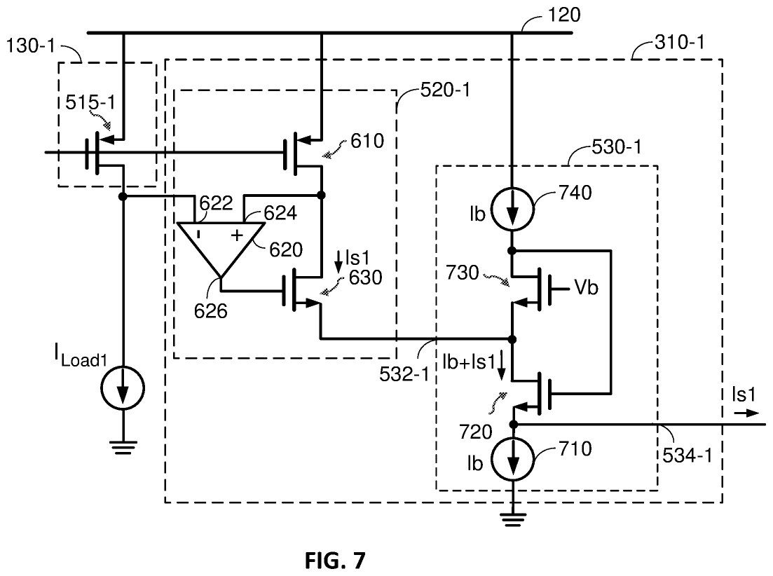

FIG. 7 shows an exemplary implementation of the current buffer 530-1 in the current sensor 310-1 according to certain aspects. It is to be appreciated that each of the other current buffers 530-2 to 530-n may be implemented with the exemplary implementation shown in FIG. 7 (e.g., each of the other current buffers 530-2 to 530-n may be a separate instance of the implementation shown in FIG. 7).

In this example, the current buffer 530-1 includes a first current source 710, a first transistor 720, a second transistor 730, and a second current source 740. The first current source 710 and the second current source 740 are configured to provide the same bias current Ib. The first current source 710 is coupled between the output 534-1 of the current buffer 530-1 and a ground (or some reference potential). The drain of the first transistor 720 (e.g., a first NFET) is coupled to the input 532-1 of the current buffer 530-1, and the source of the first transistor 720 is coupled to the output 534-1 of the current buffer 530-1.

The source of the second transistor 730 (e.g., a second NFET) is coupled to the input 532-1 of the current buffer 530-1, and the gate of the second transistor 730 is biased by a bias voltage Vb. The second current source 740 is coupled between the power grid 120 and the drain of the second transistor 730. The gate of the first transistor 720 is coupled to the drain of the second transistor 730, which forms a feedback path that provides the current buffer 530-1 with a low input impedance.

In this example, the sense current Is1 from the current mirror 520-1 flows into the input 532-1 of the current buffer 530-1. The sense current Is1 from the current mirror 520-1 and the bias current Ib from the second current source 740 flows through the first transistor 720. The sense current Is1 exits the output 534-1 of the current buffer 530-1 while the bias current Ib flows into the first current source 710. Thus, the current buffer 530-1 has unity current gain in this example. The current sources 710 and 740 do not necessarily need accurate bias circuitry across process and temperature variations as the current at the output 534-1 is independent of the bias current Ib in this example.

It is to be appreciated that the current buffer 530-1 is not limited to the exemplary implementation shown in FIG. 7, and that the current buffer 530-1 may be implemented with other configurations of transistors and/or current sources. In some implementations, the current buffer 530-1 may include a current mirror (not shown) to change the direction of the sense current Is1 at the output 534-1.

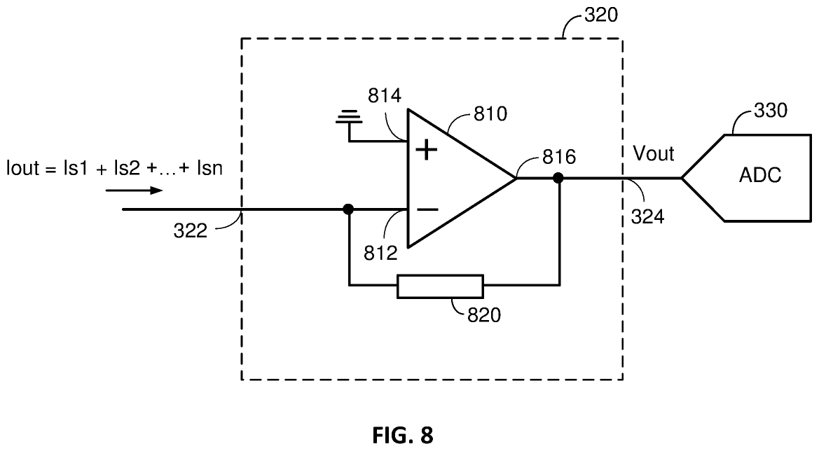

FIG. 8 shows an exemplary implementation of the transimpedance amplifier 320 according to certain aspects. In this example, the transimpedance amplifier 320 includes an operational amplifier 810 and a feedback resistor 820. The operational amplifier 810 has a first input 812, a second input 814, and an output 816. The first input 812 (e.g., minus input) is coupled to the input 322 of the transimpedance amplifier 320, the second input 814 (e.g., plus input) is coupled to a ground (or some reference potential), and the output 816 is coupled to the output 324 of the transimpedance amplifier 320. The feedback resistor 820 is coupled between the output 816 and the first input 812 of the operational amplifier 810. In this example, the transimpedance amplifier 320 may convert the current Iout (i.e., sum of the sense currents Is1 to Isn) into the output voltage Vout with a gain of approximately −Rf where Rf is the resistance of the feedback resistor 820. It is to be appreciated that the transimpedance amplifier 320 is not limited to the exemplary implementation shown in FIG. 8.

In certain aspects, the current-measurement circuit 312 may be used to measure current across multiple voltage domains. This is because the current-measurement circuit 312 measures current using current-mode current sensing, which does not rely on sensing supply voltages to measure current.

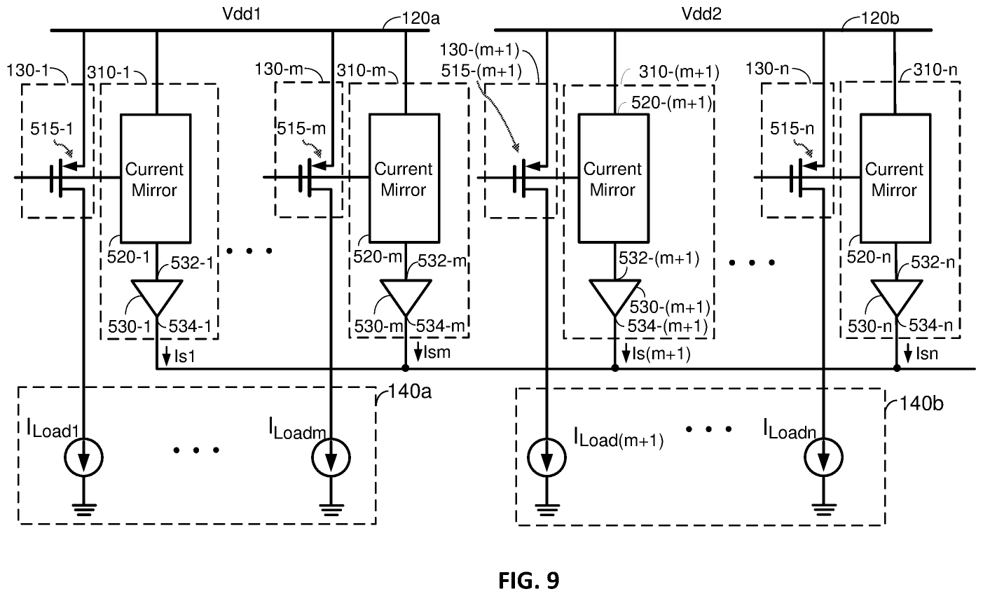

In this regard, FIG. 9 shows an example in which the current-measurement circuit 312 measure currents across a first voltage domain having a first supply voltage Vdd1 and a second voltage domain having a second supply voltage Vdd2 different from the first supply voltage Vdd1. It is to be appreciated that the current-measurement circuit 312 is not limited to two voltage domains and may be used to measure current across three or more voltage domains.

In the example in FIG. 9, the power grid 120 in FIG. 5 is divided into a first power grid 120a for the first voltage domain and a second power grid 120b for the second voltage domain. The first power grid 120a provides the first supply voltage Vdd1 and the second power grid 120b provides the second supply voltage Vdd2. Each of the first power grids 120a and the second power grid 120b may also be referred to as a supply rail, a power bus, or another term.

In this example, the circuit 140 in FIG. 5 includes a first circuit 140a in the first voltage domain and a second circuit 140b in the second voltage domain. For example, the first circuit 140a may include a first processing core and the second circuit 140b may include a second processing core.

In the example in FIG. 9, the power switches 130-1 to 130-m are coupled between the first power grid 120a and the first circuit 140a to selectively supply power to the first circuit 140a, and the power switches 130-(m+1) to 130-n are coupled between the second power grid 120b and the second circuit 140b to selectively supply power to the second circuit 140b. The power switches 130-1 to 130-m may be referred to as first power switches, and the power switches 130-(m+1) to 130-n may be referred to as second power switches.

In this example, the current sensors 310-1 to 310-m sense the load currents for the first circuit 140a and output respective sense currents Is1 to Ism to the signal routing discussed above. The current sensors 310-(m+1) to 310-n sense the load currents for the second circuit 140b and output respective sense currents Is(m+1) to Isn to the signal routing discussed above. The current sensors 310-1 to 310-m may be referred to as first current sensors, and the current sensors 310-(m+1) to 310-n may be referred to as second current sensors. Also, the sense currents Is1 to Ism may be referred to as first sense currents, and the sense currents Is(m+1) to Isn may be referred to as second sense currents. The sense currents Is1 to Ism and Is(m+1) to Isn for both voltage domains are summed at the collection node 315 (shown in FIGS. 3 and 4) and input to the input 322 of the transimpedance amplifier 320 (shown in FIGS. 3 and 4). In this example, the ADC 330 outputs a digital current measurement indicating the total current for the first circuit 140a and the second circuit 140b, in which the first circuit 140a is powered in the first voltage domain and the second circuit 140b is powered in the second voltage domain.

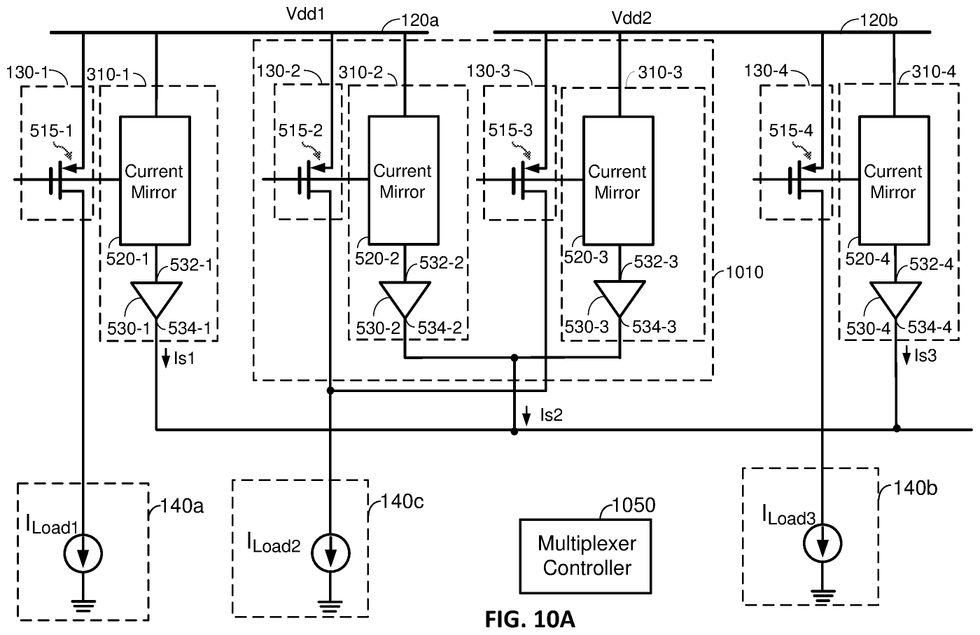

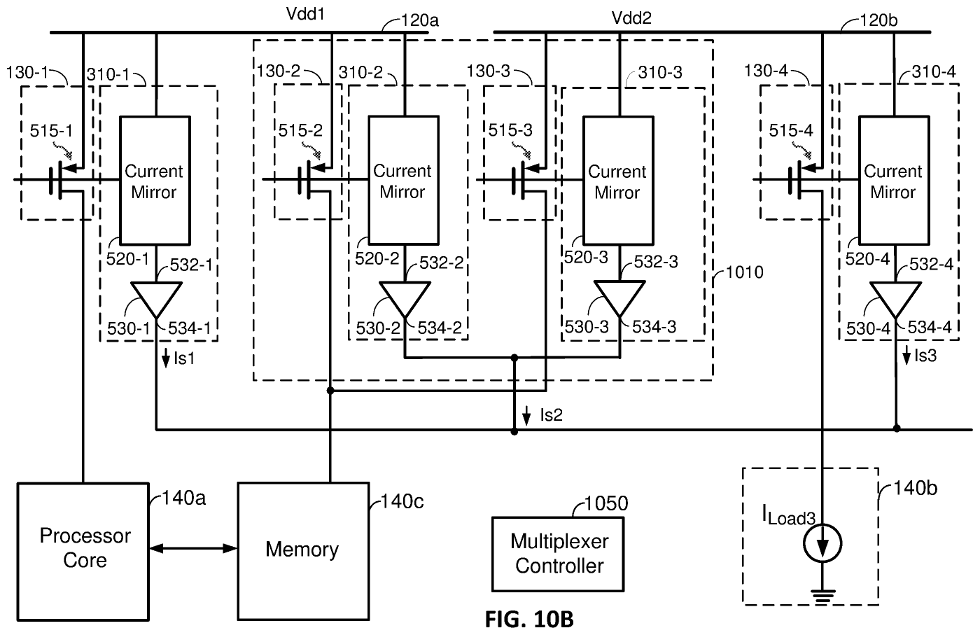

In certain aspects, one or more power multiplexers may be used to switch a circuit between two different voltage domains. In this regard, FIG. 10A shows an example of a power multiplexer 1010 configured to switch a third circuit 140c between the first voltage domain and the second voltage domain. Although one power multiplexer 1010 is shown in FIG. 10A for ease of illustration, it is to be appreciated that the chip 110 may include multiple power multiplexers (e.g., multiple instances of the power multiplexer 1010) to switch the third circuit 140c between the first voltage domain and the second voltage domain.

In the example shown in FIG. 10A, the power multiplexer 1010 includes the power switch 130-2 coupled between the first power grid 120a and the third circuit 140c, and the power switch 130-3 coupled between the second power grid 120b and the third circuit 140c. In this example, in a first mode, a power multiplexer controller 1050 may turn on the power switch 130-2 and turn off the power switch 130-3 to couple the third circuit 140c to the first power grid 120a to power the third circuit 140c in the first voltage domain. In this case, the load current I_{Load2} of the third circuit 140c shown in FIG. 10A is a combination of the load current passing through the power switch 130-2 and any leakage current (e.g., subthreshold leakage current) of the power switch 130-3. In a second mode, the power multiplexer controller 1050 may turn off the power switch 130-2 and turn on the power switch 130-3 to couple the third circuit 140c to the second power grid 120b to power the third circuit 140c in the second voltage domain. In this case, the load current I_{Load2} of the third circuit 140c is a combination of the load current passing through the power switch 130-3 and any leakage current (e.g., subthreshold leakage current) of the power switch 130-2. For case of illustration, the individual connections between the multiplexer controller 1050 and the switches 103-2 and 130-3 are not shown in FIG. 10A.

In this example, the current sensor 310-2 senses the load current passing through the power switch 130-2 and the current sensor 310-3 senses the load current passing through the power switch 130-3. The outputs of the current sensors 310-2 and 310-3 are both coupled to the signal routing to the transimpedance amplifier 320 (shown in FIGS. 3 and 4). In this example, the sense current Is2 is a combination of the sense current of the current sensor 310-2 and the sense current of the current sensor 310-3. When the third circuit 140c is powered in the first voltage domain, the current sensor 310-2 senses the load current passing through the power switch 130-2 and outputs the sense current to the signal routing. Also, the current sensor 310-3 may sense the leakage current (e.g., subthreshold leakage current) of the power switch 130-3 and output the sense current to the signal routing. When the third circuit 140c is powered in the second voltage domain, the current sensor 310-3 senses the load current passing through the power switch 130-3 and outputs the sense current to the signal routing. Also, the current sensor 310-2 may sense the leakage current (e.g., subthreshold leakage current) of the power switch 130-2 and output the sense current to the signal routing.

FIG. 10A also shows an example of the power switch 130-1 coupled between the first power grid 120a and the first circuit 140a to selectively supply power to the first circuit 140a in the first voltage domain. Although one power switch 130-1 is shown coupled between the first power grid 120a and the first circuit 140a in FIG. 10A for case of illustration, it is to be appreciated that the chip 110 may include multiple power switches coupled between the first power grid 120a and the first circuit 140a and include respective current sensors to sense the load currents passing through the power switches.

FIG. 10A also shows an example of the power switch 130-4 coupled between the second power grid 120b and the second circuit 140b to selectively supply power to the second circuit 140b in the second voltage domain. Although one power switch 130-4 is shown coupled between the second power grid 120b and the second circuit 140b in FIG. 10A for case of illustration, it is to be appreciated that the chip 110 may include multiple power switches coupled between the second power grid 120b and the second circuit 140b and include respective current sensors to sense the load currents passing through the power switches. It is to be appreciated that the first circuit 140a and/or the second circuit 140b may be omitted in some implementations.

In some implementations, the first voltage supply Vdd1 may be a core supply voltage Vddex and the second voltage supply voltage may be a memory supply voltage Vddmx. In this example, the first circuit 140a may include a processing core and/or digital logic powered by Vddcx, and the third circuit 140c may include memory that can be accessed by the first circuit 140a as shown in FIG. 10B. In this example, the third circuit 140c may be switched between Vddcx and Vddmx using the power multiplexer 1010. For example, the memory supply voltage Vddmx may be set to a voltage level that is high enough to retain the bits stored in the memory, and the core supply voltage Vddcx may be dynamically scaled (e.g., based on the workload of the first circuit 140a). In this example, the power multiplexer 1010 may switch the third circuit 140c to the memory supply voltage Vddmx when Vddcx is lower than Vddmx to retain the bits in the memory. The power multiplexer 1010 may switch the third circuit 140c to the core supply voltage Vddex when Vddcx is higher than Vddmx to provide the first circuit 140a with faster access to the memory. However, it is to be appreciated that the present disclosure is not limited to this example.

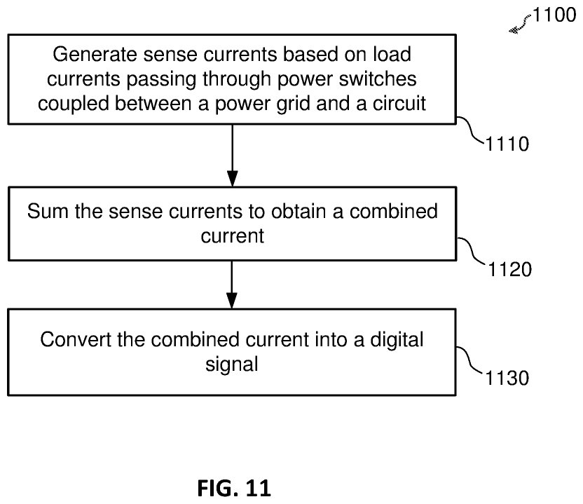

FIG. 11 illustrates a method 1100 for measuring current according to certain aspects of the present disclosure.

At block 1110, sense currents are generated based on load currents passing through power switches coupled between a power grid and a circuit. For example, the sense currents may correspond to sense currents Is1 to Isn and the power switches may correspond to power switches 130-1 to 130-n. The sense currents may be generated by the current sensors 310-1 to 310-n. In certain aspects, each of the sense currents may be proportional to a respective one of the load currents.

At block 1120, the sense currents are summed to obtain a combined current. For example, the sense currents may be summed at the collection node 315 and the combined current may correspond to the current Iout.

At block 1130, the combined current is converted into a digital signal. For example, the combined current may be converted into the digital signal by the readout circuit 314. In some implementations, the readout circuit 314 may include the transimpedance amplifier 320 and the ADC 330.

In certain aspects, converting the combined current into the digital circuit includes converting the combined current into a voltage and converting the voltage into the digital signal. The transimpedance amplifier 320 may convert the combined current into the voltage, and the ADC 330 may convert the voltage into the digital signal.

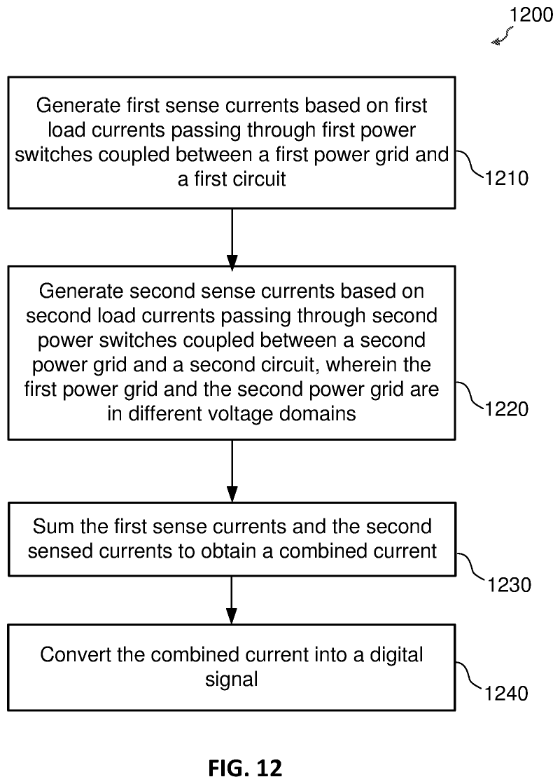

FIG. 12 illustrates another example of a method 1200 for measuring current according to certain aspects.

At block 1210, first sense currents are generated based on first load currents passing through first power switches coupled between a first power grid and a first circuit. For example, the first sense currents may correspond to sense currents Is1 to Ism, the first load currents may correspond to load currents I_{Load} to I_{Loadm}, the first power grid may correspond to the first power grid 120a, and the first power switches may correspond to the power switches 130-1 to 130-m. The first sense currents may be generated by the current sensors 310-1 to 310-m.

At block 1220, second sense currents are generated based on second load currents passing through second power switches coupled between a second power grid and a second circuit, wherein the first power grid and the second power grid are in different voltage domains. For example, the second sense currents may correspond to sense currents Is(m+1) to Isn, the second load currents may correspond to load currents I_{Load(m+1)} to I_{Loadn}, the second power grid may correspond to the second power grid 120b, and the second power switches may correspond to the power switches 130-(m+1) to 130-n. The second sense currents may be generated by the current sensors 310-(m+1) to 310-n.

At block 1230, the first sense currents and the second sense currents are summed to obtain a combined current. For example, the sense currents may be summed at the collection node 315 and the combined current may correspond to the current Iout.

At block 1240, the combined current is converted into a digital signal. For example, the combined current may be converted into the digital signal by the readout circuit 314. In some implementations, the readout circuit 314 may include the transimpedance amplifier 320 and the ADC 330.

In certain aspects, converting the combined current into the digital circuit includes converting the combined current into a voltage and converting the voltage into the digital signal. The transimpedance amplifier 320 may convert the combined current into the voltage, and the ADC 330 may convert the voltage into the digital signal.

Implementation examples are described in the following numbered clauses:

1. A chip, comprising:
a power grid;
power switches coupled between the power grid and a circuit;
current sensors configured to generate sense currents based on load currents
passing through the power switches;
a readout circuit having an input and an output; and
signal routing coupling the current sensors to the input of the readout circuit.

2. The chip of clause 1, wherein each of the sense currents is proportional to a
respective one of the load currents.

3. The chip of clause 1 or 2, wherein each of the power switches comprises a
respective switch transistor.

4. The chip of any one of clauses 1 to 3, wherein each of the power switches comprises a respective p-type field effect transistor (PFET).

5. The chip of any one of clauses 1 to 4, wherein each of the current sensors comprises:
a respective current mirror coupled to a gate of a respective one of the power switches; and
a respective current buffer having an input and an output, wherein the input of the respective current buffer is coupled to the respective current mirror, and the output of the respective current buffer is coupled to the signal routing.

6. The chip of clause 5, wherein each of the power switches comprises a respective switch transistor.

7. The chip of clause 5 or 6, wherein the respective current mirror of each of the current sensors comprises:
a respective sense transistor, wherein a gate of the respective sense transistor is coupled to the gate of the respective one of the power switches, and a source of the respective sense transistor is coupled to the power grid;
a respective amplifier having a first input, a second input, and an output, wherein the first input of the respective amplifier is coupled to a drain of the respective one of the power switches, and the second input of the respective amplifier is coupled to a drain of the respective sense transistor; and
a respective feedback transistor, wherein a drain of the respective feedback transistor is coupled to a drain of the respective sense transistor, a gate of the respective feedback transistor is coupled to the output of the respective amplifier, and a source of the respective feedback transistor is coupled to the input of the respective current buffer.

8. The circuit of any one of clauses 1 to 7, wherein the readout circuit comprises:
a transimpedance amplifier having an input and an output, wherein the input of the transimpedance amplifier is coupled to the input of the readout circuit, and
an analog-to-digital converter (ADC) coupled to the output of the transimpedance amplifier.

9. The chip of clause 8, wherein the transimpedance amplifier comprises:
an operational amplifier having a first input, a second input, and an output, wherein the first input of the operational amplifier is coupled to the input of the transimpedance amplifier, the second input of the operational amplifier is coupled to a ground, and the output of the operational amplifier is coupled to the output of the transimpedance amplifier; and
a feedback resistor coupled between the output of the operational amplifier and the first input of the operational amplifier.

10. The chip of clause 8 or 9, wherein the transimpedance amplifier is configured to convert a sum of the sense currents at the input of the transimpedance amplifier into an output voltage at the output of the transimpedance amplifier.

11. The chip of any one of clauses 1 to 10, wherein the readout circuit is configured to convert a sum of the sense currents at the input of the readout circuit into a digital signal.

12. A chip, comprising:
a first power grid configured to provide a first supply voltage;
a second power grid configured to provide a second supply voltage different from the first supply voltage;
first power switches coupled between the first power grid and a first circuit;
second power switches coupled between the second power grid and a second circuit;
first current sensors configured to generate first sense currents based on first load currents passing through the first power switches;
second current sensors configured to generate second sense currents based on second load currents passing through the second power switches;
a readout circuit having an input and an output; and
signal routing coupling the first current sensors and the second current sensors to the input of the readout circuit.

13. The chip of clause 12, wherein:
each of the first sense currents is proportional to a respective one of the first load currents; and
each of the second sense currents is proportional to a respective one of the second load currents.

14. The chip of clause 12 or 13, wherein each of the first current sensors comprises:
a respective current mirror coupled to a gate of the respective one of the first power switches; and
a respective current buffer having an input and an output, wherein the input of the respective current buffer is coupled to the respective current mirror, and the output of the respective current buffer is coupled to the signal routing.

15. The chip of clause 14, wherein each of the second current sensors comprises:
a respective current mirror coupled to a gate of the respective one of the second power switches; and
a respective current buffer having an input and an output, wherein the input of the respective current buffer is coupled to the respective current mirror, and the output of the respective current buffer is coupled to the signal routing.

16. The chip of any one of clauses 12 to 15, wherein the readout circuit comprises:
a transimpedance amplifier having an input and an output, wherein the input of the transimpedance amplifier is coupled to the input of the readout circuit, and
an analog-to-digital converter (ADC) coupled to the output of the transimpedance amplifier.

17. The chip of clause 16, wherein the transimpedance amplifier is configured to convert a sum of the first sense currents and the second sense currents at the input of the transimpedance amplifier into an output voltage at the output of the transimpedance amplifier.

18. The chip of any one of clauses 12 to 17, wherein the readout circuit is configured to convert a sum of the first sense currents and the second sense currents at the input of the readout circuit into a digital signal.

19. The chip of any one of clauses 12 to 18, further comprising:
third power switches coupled between the first power grid and the second circuit; and
third current sensors configured to generate third sense currents based on third load currents passing through the third power switches, wherein the signal routing couples the third current sensors to the input of the readout circuit.

20. The chip of clause 19, wherein the first circuit comprises a processor core, and the second circuit comprises a memory.

21. The chip of clause 19 or 20, further comprising a multiplexer controller configured to:
turn on the second power switches and turn off the third power switches in a first mode; and
turn off the second power switches and turn on the third power switches in a second mode.

22. A method for measuring current, comprising:
generating sense currents based on load currents passing through power switches coupled between a power grid and a circuit;
summing the sense currents to obtain a combined current; and
converting the combined current into a digital signal.

23. The method of clause 22, wherein each of the sense currents is proportional to a
respective one of the load currents.

24. The method of clause 22 or 23, wherein converting the combined current into the digital signal comprises:
converting the combined current into a voltage; and
converting the voltage into the digital signal.

25. A method for measuring current, comprising:
generating first sense currents based on first load currents passing through first power switches coupled between a first power grid and a first circuit;
generating second sense currents based on second load currents passing through second power switches coupled between a second power grid and a second circuit, wherein the first power grid and the second power grid are in different voltage domains;
summing the first sense currents and the second sense currents to obtain a combined current;
converting the combined current into a digital signal.

26. The method of clause 25, wherein:
each of the first sense currents is proportional to a respective one of the first load currents; and
each of the second sense currents is proportional to a respective one of the second load currents.

27. The method of clause 25 or 26, wherein converting the combined current into the digital signal comprises:
converting the combined current into a voltage; and
converting the voltage into the digital signal.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect electrical coupling between two structures. It is also to be appreciated that the term “ground” may refer to a DC ground or an AC ground, and thus the term “ground” covers both possibilities.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element. Also, it is to be understood that numerical designations used to distinguish elements in the description do not necessarily match numerical designations used for corresponding elements in the claims.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a power grid;
power switches coupled between the power grid and a circuit;
current sensors configured to generate sense currents based on load currents passing through the power switches;
a readout circuit having an input and an output; and
signal routing coupling the current sensors to the input of the readout circuit.

2. The chip of claim 1, wherein each of the sense currents is proportional to a respective one of the load currents.

3. The chip of claim 1, wherein each of the power switches comprises a respective switch transistor.

4. The chip of claim 1, wherein each of the power switches comprises a respective p-type field effect transistor (PFET).

5. The chip of claim 1, wherein each of the current sensors comprises:
a respective current mirror coupled to a gate of a respective one of the power switches; and
a respective current buffer having an input and an output, wherein the input of the respective current buffer is coupled to the respective current mirror, and the output of the respective current buffer is coupled to the signal routing.

6. The chip of claim 5, wherein each of the power switches comprises a respective switch transistor.

7. The chip of claim 5, wherein the respective current mirror of each of the current sensors comprises:
a respective sense transistor, wherein a gate of the respective sense transistor is coupled to the gate of the respective one of the power switches, and a source of the respective sense transistor is coupled to the power grid;
a respective amplifier having a first input, a second input, and an output, wherein the first input of the respective amplifier is coupled to a drain of the respective one of the power switches, and the second input of the respective amplifier is coupled to a drain of the respective sense transistor; and
a respective feedback transistor, wherein a drain of the respective feedback transistor is coupled to a drain of the respective sense transistor, a gate of the respective feedback transistor is coupled to the output of the respective amplifier, and a source of the respective feedback transistor is coupled to the input of the respective current buffer.

8. The circuit of claim 1, wherein the readout circuit comprises:
a transimpedance amplifier having an input and an output, wherein the input of the transimpedance amplifier is coupled to the input of the readout circuit, and an analog-to-digital converter (ADC) coupled to the output of the transimpedance amplifier.

9. The chip of claim 8, wherein the transimpedance amplifier comprises:
an operational amplifier having a first input, a second input, and an output, wherein the first input of the operational amplifier is coupled to the input of the transimpedance amplifier, the second input of the operational amplifier is coupled to a ground, and the output of the operational amplifier is coupled to the output of the transimpedance amplifier; and
a feedback resistor coupled between the output of the operational amplifier and the first input of the operational amplifier.

10. The chip of claim 8, wherein the transimpedance amplifier is configured to convert a sum of the sense currents at the input of the transimpedance amplifier into an output voltage at the output of the transimpedance amplifier.

11. The chip of claim 1, wherein the readout circuit is configured to convert a sum of the sense currents at the input of the readout circuit into a digital signal.

12. A chip, comprising:
a first power grid configured to provide a first supply voltage;
a second power grid configured to provide a second supply voltage different from the first supply voltage;
first power switches coupled between the first power grid and a first circuit;
second power switches coupled between the second power grid and a second circuit;
first current sensors configured to generate first sense currents based on first load currents passing through the first power switches;
second current sensors configured to generate second sense currents based on second load currents passing through the second power switches;
a readout circuit having an input and an output; and
signal routing coupling the first current sensors and the second current sensors to the input of the readout circuit.

13. The chip of claim 12, wherein:
each of the first sense currents is proportional to a respective one of the first load currents; and
each of the second sense currents is proportional to a respective one of the second load currents.

14. The chip of claim 12, wherein each of the first current sensors comprises:
a respective current mirror coupled to a gate of the respective one of the first power switches; and
a respective current buffer having an input and an output, wherein the input of the respective current buffer is coupled to the respective current mirror, and the output of the respective current buffer is coupled to the signal routing.

15. The chip of claim 14, wherein each of the second current sensors comprises:
a respective current mirror coupled to a gate of the respective one of the second power switches; and
a respective current buffer having an input and an output, wherein the input of the respective current buffer is coupled to the respective current mirror, and the output of the respective current buffer is coupled to the signal routing.

16. The chip of claim 12, wherein the readout circuit comprises:
a transimpedance amplifier having an input and an output, wherein the input of the transimpedance amplifier is coupled to the input of the readout circuit, and an analog-to-digital converter (ADC) coupled to the output of the transimpedance amplifier.

17. The chip of claim 16, wherein the transimpedance amplifier is configured to convert a sum of the first sense currents and the second sense currents at the input of the transimpedance amplifier into an output voltage at the output of the transimpedance amplifier.

18. The chip of claim 12, wherein the readout circuit is configured to convert a sum of the first sense currents and the second sense currents at the input of the readout circuit into a digital signal.

19. The chip of claim 12, further comprising:
third power switches coupled between the first power grid and the second circuit; and
third current sensors configured to generate third sense currents based on third load currents passing through the third power switches, wherein the signal routing couples the third current sensors to the input of the readout circuit.

20. The chip of claim 19, wherein the first circuit comprises a processor core, and the second circuit comprises a memory.

21. The chip of claim 19, further comprising a multiplexer controller configured to:
turn on the second power switches and turn off the third power switches in a first mode; and
turn off the second power switches and turn on the third power switches in a second mode.

22. A method for measuring current, comprising:
generating sense currents based on load currents passing through power switches coupled between a power grid and a circuit;
summing the sense currents to obtain a combined current; and
converting the combined current into a digital signal.

23. The method of claim 22, wherein each of the sense currents is proportional to a respective one of the load currents.

24. The method of claim 22, wherein converting the combined current into the digital signal comprises:
converting the combined current into a voltage; and
converting the voltage into the digital signal.

25. A method for measuring current, comprising:
generating first sense currents based on first load currents passing through first power switches coupled between a first power grid and a first circuit;
generating second sense currents based on second load currents passing through second power switches coupled between a second power grid and a second circuit, wherein the first power grid and the second power grid are in different voltage domains;
summing the first sense currents and the second sense currents to obtain a combined current;
converting the combined current into a digital signal.

26. The method of claim 25, wherein:
each of the first sense currents is proportional to a respective one of the first load currents; and
each of the second sense currents is proportional to a respective one of the second load currents.

27. The method of claim 25, wherein converting the combined current into the digital signal comprises:
converting the combined current into a voltage; and
converting the voltage into the digital signal.
